(19) United States
(12) Patent Application Publication
(10) Pub. No.: US 2006/0096737 A1
(43) Pub. Date: May 11, 2006

(54) Heat exchanger

(75) Inventor: Naoki Kimura, Tokyo (JP)

Correspondence Address: BIRCH STEWART KOLASCH & BIRCH, PO BOX 747, FALLS CHURCH, VA, 22040-0747, US

(73) Assignee: THE FURUKAWA ELECTRIC CO., LTD.

(21) Appl. No.: 11/315,191

(22) Filed: Dec. 23, 2005

Related U.S. Application Data
(63) Continuation of application No. PCT/JP04/09690, filed on Jul. 1, 2004.

(30) Foreign Application Priority Data
Jul. 4, 2003 (JP) 2003-271047

(51) Int. Cl. H05K 7/20

(52) U.S. Cl. 165/80.3; 361/704

(57) ABSTRACT

A heat exchanger having a plurality of fin plates (2) provided in parallel on a face (1a) of a base (1), wherein the fin plate (2) is provided with a rectifier portion (2b) having a tapered cross sectional shape at, at least, one tip (2a) thereof.

### TECHNICAL FIELD

The present invention relates to a heat exchanger.

### BACKGROUND ART

A heat exchanger for cooling heat-generating parts, such as electronic parts, has a plurality of fin plates 12 provided in parallel on a face 1a of a base (substrate) 1, as shown in FIGS. 7(a) and 7(b). The heat-generating parts (not shown) are in thermal contact with a face 1b opposite to the face, 1a of the base on which the fin plates 12 are provided, and heat is dissipated (e.g. cooled by blowing) from the fin plates 12 through a heat exchanging medium.

In the meanwhile, since the performance of electronic parts and the like has been improved in recent years, with a resultant increase in the amount of heat generation, conventional heat exchangers have come to lack sufficient cooling effect. Accordingly, the heat exchanger needs further improved cooling efficiency.

Other and further features and advantages of the invention will appear more fully from the following description, taken in connection with the accompanying drawings.

### BRIEF DESCRIPTION OF THE DRAWINGS

FIG. 1(a) is a perspective view showing a first embodiment of the heat exchanger of the present invention; and FIG. 1(b) is a partial plan view thereof.

FIGS. 2(a), 2(b) and 2(c) are partial plan views showing second, third and fourth embodiments, respectively, of the heat exchanger of the present invention.

FIGS. 3(a) and 3(b) are explanatory views showing steps of an example of embodiments of the method for producing the fin plate that can be used in the heat exchanger of the present invention.

FIG. 4 shows a vertical cross section of the fin plate to which tools for expanding the heat dissipation area are attached.

FIG. 5(a) is a partial cross section of the fin plate in a conventional heat exchanger; and FIGS. 5(b) and 5(c) are partial cross sections of the fin plate in the heat exchanger of the present invention, each showing an aspect of a rectifier portion which is provided to be a tapered shape at the tip of each fin plate.

FIGS. 6(a) to 6(d) are partial cross sections of the fin plate in the heat exchanger of the present invention, each showing another aspect of a rectifier portion which is provided to be a tapered shape at the tip of the fin plate.

FIG. 7(a) is a perspective view of a conventional heat exchanger; and FIG. 7(b) is a partial plan view thereof.

### DISCLOSURE OF THE INVENTION

In the heat exchanger of the present invention, the principal feature is to provide fin plates having a shape for facilitating a heat exchange medium to flow and pass through between the fins.

That is, the heat exchanger of the present invention is a heat exchanger, which comprises a plurality of fin plates provided (aligned) in parallel on a face of a base, wherein the fin plate comprises a rectifier portion having a tapered cross sectional shape at, at least, one tip of the fin plate, and wherein, in addition to the above, preferably, the heat exchanger comprises said fin plate having flat faces on both sides thereof.

Herein, the term “being a tapered cross sectional shape at, at least, one tip of the fin plate” means that the thickness of the cross section of the fin plate is reduced toward the tip of the fin plate.

### BEST MODE FOR CARRYING OUT THE INVENTION

It was accomplished to improve cooling efficiency of a heat exchanger, by improving the shape of the fin plate.

According to the heat exchanger of the present invention, solved can be problems in conventional heat exchangers, i.e. problems that a heat exchange medium can hardly flow and pass through between fin plates, such that an insufficient heat dissipating effect is attained by the fin plates, with the result that electronic parts and the like generating enhanced heat cannot be sufficiently cooled.

In the heat exchanger of the present invention, the heat exchange medium easily flows between the fin plates, because the rectifier portion, whose shape is a tapered cross section, is provided at the tip of the fin plate. Further, the heat exchange medium is also able to pass through between the fin plates with less resistance, by forming both faces of the fin plate to be flat. Consequently, there is such an advantage that heat dissipation from the fin plate becomes favorable, to render the heat exchanger improved in cooling efficiency.

Productivity of the heat exchanger is improved, by providing the rectifier portion of the fin plate at the tip of the fin plate by machining, for example, molding. A recommended process for forming the fin plate with particularly high productivity is to cut an extruded material by, for example, press cutting in a longitudinal direction.

The present invention is described in more detail hereinafter based on exemplified examples, with reference to drawings, but the invention is by no means restricted to these. EXAMPLES

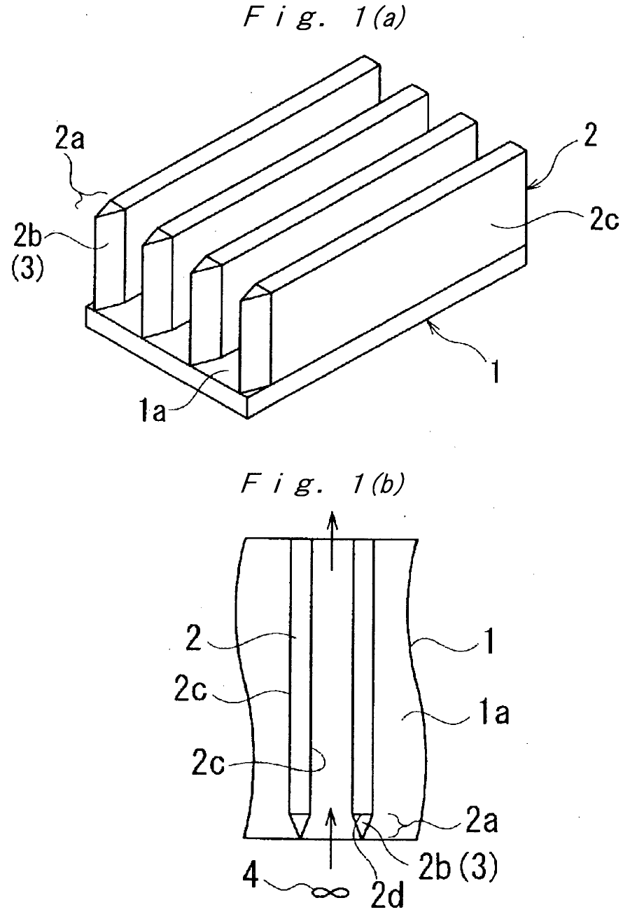

FIG. 1(a) is a perspective view showing an example of the first embodiment of the heat exchanger of the present invention; and FIG. 1(b) is a partial plan view thereof. In all of the figures for describing the present invention, the same reference numerals are given to those having the same function, and repeated descriptions of them are omitted.

In the heat exchanger, a plurality of fin plates 2 are provided in parallel on the face 1a of a base 1, and a rectifier portion 2b having a tapered cross section shape is provided at an end 2a of the fin plate 2, in which faces 2c on both sides of the fin plate 2 each are a flat face. The rectifier portion 2b is formed with a rod body 3 having a triangular cross section, one side face of which is brazed to an end face 2d of the fin plate 2.

In the heat exchanger, a heat exchange medium feed device 4 (for example, a fan can be enumerated, which is referred to as a “fan” hereinafter) is disposed in front of the rectifier portion 2b, as shown in FIG. 1(b).

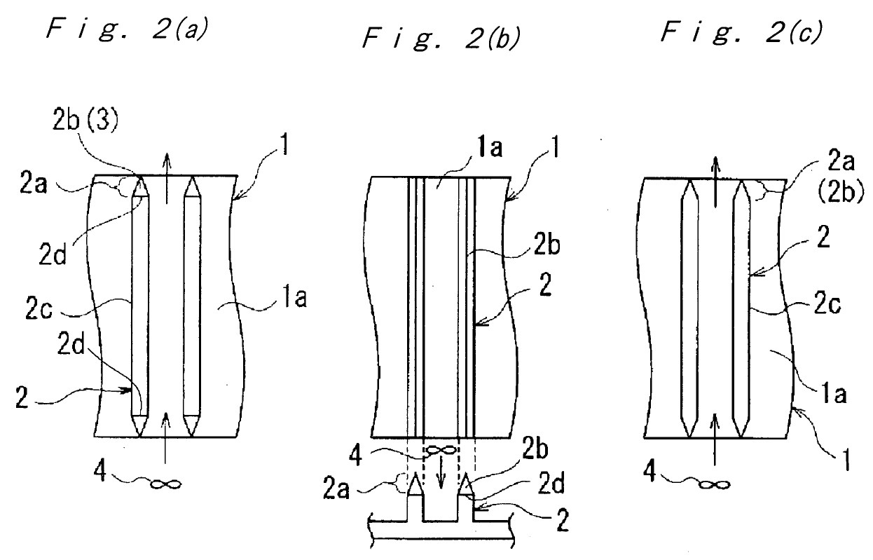

FIGS. 2(a) to 2(c) are partial plan views each showing another embodiment of the heat exchanger of the present invention. In FIG. 2(a), the rectifier portions 2b are provided at both ends 2d of the fin plate 2, by which cooling efficiency is further improved, since rectified flow of the heat exchange medium is maintained up to the exit portion of the fin plate. In FIG. 2(b), the rectifier portion 2b is provided on the upper end 2a of the fin plate, in which the fan 4 is located above the heat exchanger. In FIG. 2(c), the rectifier portion 2b is integrated with the fin plate by machining the tip 2a of the fin plate 2 to be tapered.

In the present invention, the method for machining both ends 2a of the fin plate 2 to be integrated with the fin plate to be tapered in shape (see FIG. 2(c)) is more excellent in productivity, compared with the method for attaching a rod body(s) 3 prepared as a separate part(s) by, for example, brazing (see FIGS. 1(a) and 1(b), and FIGS. 2(a) and 2(b)) to one end or both ends 2a of the fin plate 2.

Any method, including a cutting method, a swart cutting method, a forging method, and a chemical polishing method, may be used for machining the end 2a of the fin plate 2 into a tapered shape.

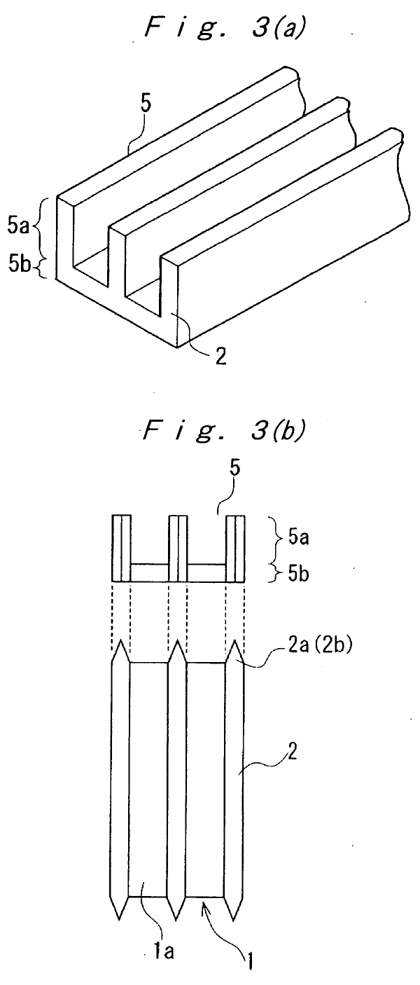

For the method for producing the fin plate 2, a recommended method excellent in productivity is to press-cut an extruded material 5 with a blade that is formed so that the tip of a crest (peak) 5a of the extruded material is machined into a tapered shape, as shown in FIG. 3(a) and 3(b). The base portion 5b of the extruded material may be directly used as the base 1.

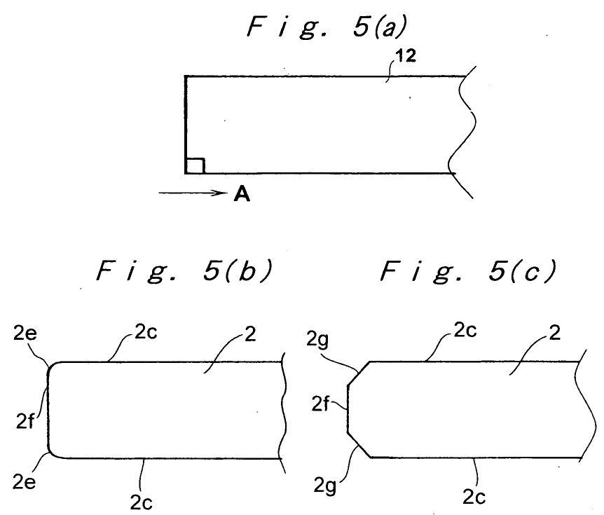

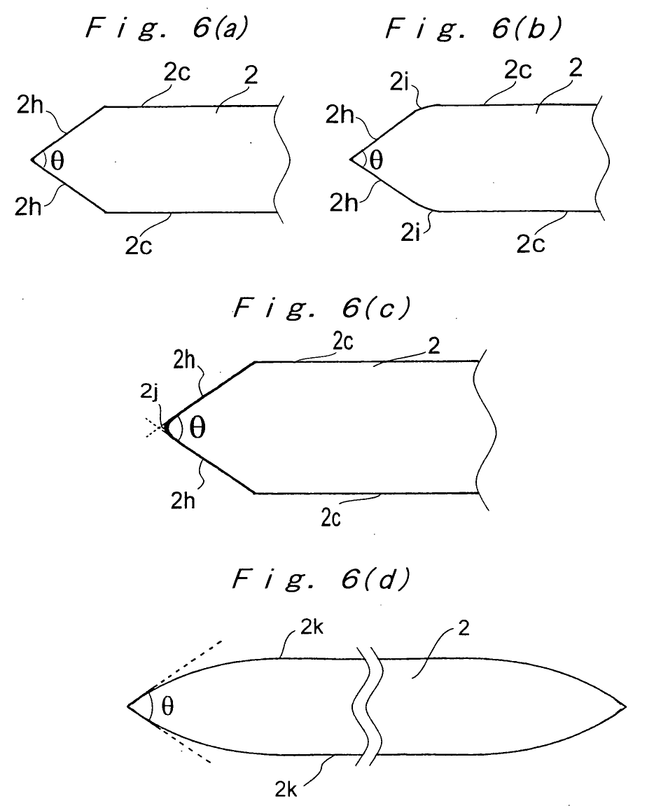

In the present invention, it is preferable to apply some safety measures, such as rounding the tip, depending on work environments, since the tapered chip, which may cause an incised wound, is danger. FIGS. 5(b) and 6(c) show examples thereof. In the figures, the tips 2e and 2j, respectively, are rounded.

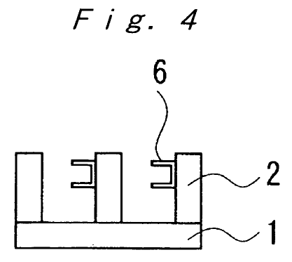

To the heat exchanger of the present invention, a heat-dissipating area expanding tool 6 having a cross sectional shape as shown, for example, in FIG. 4 may be readily provided, by forming the face of the fin plate flat. In the present invention, any shape can be used for the heat-dissipating area expanding tool. Further, a heat pipe may be attached to the base, if necessary, in the present invention.

In the present invention, the fin plate (2) is provided with the rectifier portion having a tapered cross sectional shape at, at least, one end of the fin plate. In other words, the thickness of the cross section of the fin plate is reduced toward at least at one end of the plate. For example, the thickness of the cross section of the fin plate is reduced toward at least one tip end of the plate in the longitudinal direction (the direction of advance of the heat exchange medium) (see, for example, FIGS. 1(a) and 1(b), and FIGS. 2(a) and 2(c)), or it is reduced toward the upper end of the fin plate in the transverse direction of the plate (in the direction perpendicular to the plane face (1a) of the base (1) (see, for example, FIG. 2(b)). The tapered shape is not particularly limited, and the fin plate is sufficient in a shape having no corner of 90° as viewed from the inside of the fin (see the conventional fin plate (12), as shown in a partial cross section in FIG. 5(a). The angle of 90° shown in the figure means that the angle against the flow direction of the heat exchange medium shown by an arrow (A) in the figure is 90°), or, in other words, the corner may be chamfered. For example, as shown in FIG. 5(b), the corners formed between the top face 2f of the fin plate and each of faces 2c are chamfered to round them (2e in the figure), or aslant faces (2g) may be formed by cutting the corners formed between the top face 2f of the fin plate and each of faces 2c, as shown in FIG. 5(c). Providing a tapered tip is preferable among these methods, and examples thereof are schematically shown in FIGS. 6(a) to 6(d). The tip is preferably formed with an angle (θ) of 10° to 100°. FIG. 6(a) shows an example in which the tip of the fin plate 2 is formed with two faces 2h. FIG. 6(b) shows an example, in which the tip is formed with the two faces 2h in the same manner as in FIG. 6(a), and in which, further, the corner formed between the faces 2h and 2c is rounded (2i in the figure). FIG. 6(c) shows an example, in which the tip is formed with the two faces 2h, and in which, further, the corner formed between the two faces 2h is rounded (2j in the figure). FIG. 6(d) shows an example, in which both faces 2k of the fin plate 2 are curved, and the entire shape of the plate is to be streamlined.

In the present invention, as a method for allowing the heat-generating parts (not shown) to make thermal contact (close contact) with the base, use can be made, for example, of a brazing method, a screw fixing method, a socketting (plugging) method, a wire binding method, and the like. The heat-generating parts may be allowed to directly contact the face opposite to the face of the base on which the fin plate is provided, or they may be allowed to contact via, for example, a heat pipe, heat conducting sheet, or heat conducting grease.

The heat exchanger of the present invention is able to exhibit an excellent cooling effect when applied to electronic parts, as well as to engine ECUs, battery ECUs, batteries themselves, car-mounted electronic appliances (so-called car stereo-players and car navigation systems), mobile phones, compact game machines, and the like.

Further, the heat-generating body to which the heat exchanger of the present invention is applied is not limited to electronic appliances; rather, the heat exchanger of this invention may be applied to any kind of heat-generating bodies.

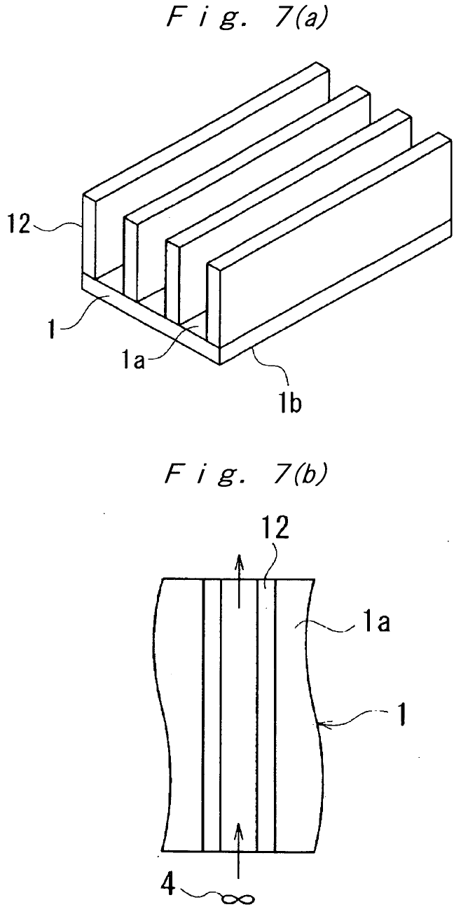

Respective large electronic components were brought into thermal contact with the back face of the base of each heat exchanger shown in FIGS. 1(a) and 1(b), and FIGS. 2(a) to 2(c), and heat dissipation characteristics (amount of heat dissipation) of the respective heat exchangers were examined in a usual manner. For comparison, heat dissipation characteristics of the conventional heat exchanger, as shown in FIGS. 7(a) and 7(b), and of a conventional heat exchanger having curved side faces of the fin plate (the same as those shown in FIGS. 7(a) and 7(b), except that the center portion of the side faces of the fin plate in the blow direction was bulged), were also examined in the same manner. The size of the base was 600 mm in length, 600 mm in width, and 10 mm in thickness; the size of the fin plate was 600 mm in length, 200 mm in height, and 3 mm in thickness; and the number of fin plates was 27; and the distance between the fin plates was about 20 mm. The results are shown in Table 1. The amount of heat dissipation was represented by ratios (relative values), assuming the amount of heat dissipation of the conventional heat exchanger shown in FIGS. 7(a) and 7(b) to be 100.

TABLE 1

| | | Heat exchangers of this invention | | | | Conventional heat exchangers | |
|---|---|---|---|---|---|---|---|
| Classification | | FIGS. 1(a), (b) | FIG. 2(a) | FIG. 2(b) | FIG. 2(c) | FIGS. 7(a), (b) | Not shown |
| Rectifier | Inlet side | Provided | Provided | Provided | Provided | Not provided | Not provided |
| part | Outlet side | Not provided | Provided | — | Provided | Not provided | Not provided |

| | | | | | | |
|---|---|---|---|---|---|---|
| Shape of face | Flat | Flat | Flat | Flat | Flat | Curved |
| Amount of heat dissipation | 120 | 125 | 115 | 125 | 100 | 95 |

As is apparent from Table 1, the amount of heat dissipation of all the heat exchangers of the present invention was higher by at least 15% to 25% than that of the conventional heat exchangers. This is because the rectifier portion was provided at the end of the fin plate, and both side faces of the fin plate were formed flat, so that air could smoothly flow and pass through between the fin plates. The amount of heat dissipation (heat-dissipating ability) of the conventional heat exchanger having curved side faces of the fin plate was further decreased than the amount of heat dissipation of the conventional heat exchanger having flat faces (FIGS. 7(a) and 7(b)). This is because the curved portion (bulged portion) interfered with air blowing.

### INDUSTRIAL APPLICABILITY

The heat exchanger of the present invention is preferable for cooling heat-generating members, such as electronic parts (for example, power transistors, CPUs, HDDs, ICs, memories, and capacitors).

Having described our invention as related to the present embodiments, it is our intention that the invention not be limited by any of the details of the description, unless otherwise specified, but rather be construed broadly within its spirit and scope as set out in the accompanying claims.

1. A heat exchanger, comprising a plurality of fin plates provided in parallel on a face of a base, wherein the fin plate is provided with a rectifier portion having a tapered cross sectional shape at, at least, one tip thereof.

2. The heat exchanger according to claim 1, wherein the tapered tip of the fin plate is rounded.

3. The heat exchanger according to claim 1, wherein the rectifier portion is provided by machining the tip of the fin plate.

4. The heat exchanger according to claim 1, wherein the rectifier portion is provided by blazing at the tip of the fin plate.

5. The heat exchanger according to claim 1, wherein the fin plate has flat faces on both sides thereof.

6. The heat exchanger according to claim 5, wherein the tapered tip of the fin plate is rounded.

7. The heat exchanger according to claim 5, wherein the rectifier portion is provided by machining the tip of the fin plate.

8. The heat exchanger according to claim 5, wherein the rectifier portion is provided by blazing at the tip of the fin plate.

9. The heat exchanger according to claim 5, wherein the face of the fin plate has a heat dissipation area expanding tool.

10. The heat exchanger according to claim 9, wherein the tapered tip of the fin plate is rounded.

11. The heat exchanger according to claim 9, wherein the rectifier portion is provided by machining the tip of the fin plate.

12. The heat exchanger according to claim 9, wherein the rectifier portion is provided by blazing at the tip of the fin plate.

13. The heat exchanger according to claim 5, wherein the plural fin plates are formed by cutting an extruded material in the longitudinal direction.

14. The heat exchanger according to claim 13, wherein the tapered tip of the fin plate is rounded.

15. The heat exchanger according to claim 13, wherein the rectifier portion is provided by machining the tip of the fin plate.

16. The heat exchanger according to claim 13, wherein the rectifier portion is provided by blazing at the tip of the fin plate.

17. The heat exchanger according to claim 13, wherein the face of the fin plate has a heat dissipation area expanding tool.

18. The heat exchanger according to claim 17, wherein the tapered tip of the fin plate is rounded.

19. The heat exchanger according to claim 17, wherein the rectifier portion is provided by machining the tip of the fin plate.

20. The heat exchanger according to claim 17, wherein the rectifier portion is provided by blazing at the tip of the fin plate.
